(19) United States
(12) Patent Application Publication
(10) Pub. No.: US 2012/0257345 A1
(43) Pub. Date: Oct. 11, 2012

(54) TRIPOD ADAPTER OR STAND FOR HANDHELD ELECTRONIC DEVICES

(76) Inventor: Kelvin G. Hulet, Cedar Hills, UT (US)

(21) Appl. No.: 13/440,760

(22) Filed: Apr. 5, 2012

Related U.S. Application Data
(60) Provisional application No. 61/471,908, filed on Apr. 5, 2011.

(51) Int. Cl. G06F 1/16; B23P 11/00; H05K 7/00

(52) U.S. Cl. 361/679.32; 248/316.4; 29/428

(57) ABSTRACT

An adapter which enables nearly any smartphone or electronic device to be securely coupled to a holder for placing at a desired orientation on a support surface or tripod camera mount. The adapter may include first and second brackets slidably joined together with one another and moveable to expand away from, and contract toward, one another along an operating path. Each bracket may have a slider and a jaw that is generally orthogonal to the sliding portion. The jaw of each bracket may have a clamping face that makes an acute angle with the slider and is opposed to the clamping face of the other bracket. The clamping faces may be coated with a resilient, slip resistant material. A securement portion may be provided to allow the jaws to be set at a desired distance.

### PRIORITY

This application claims priority to U.S. Provisional Patent Application No. 61/471,908 entitled TRIPOD ADAPTER/STAND FOR SMARTPHONES filed on Apr. 5, 2011, which is incorporated herein by reference in its entirety.

### FIELD

This disclosure relates generally to holders for electronic devices, such as smartphones, tablet computer, video games, etc. More particularly, it relates to stands which can also serve as adapters for securing a camera-equipped electronic device to a tripod.

### BACKGROUND

Mobile electronic devices such as smartphones, tablet computers, and handheld video games (such as PSP, Gameboy Advance, etc.), GPS, media players (iPod Touch, mp3 players, video players and recorders, etc.) offer more advanced computing ability and connectivity than older mobile electronic devices. These devices are essentially handheld computers, some integrated within a mobile communications capabilities, such as telephone 3G, 4G, WiFi, etc. Growth in demand for smartphones, tablets, and other devices having powerful processors, abundant memory, larger screens, powerful and open operating systems have dominated the mobile electronics phone market and are now making headway into the laptop market.

Tens of millions of Americans now own and use mobile electronic devices on a regular basis. The increased functionality of these devices, and particularly of smartphones and tablet computers has lead to them being used to stream video and audio, play games, read ebooks, browse the internet, attach to keyboards and other peripherals, teleconference, record video, function as a GPS and navigational system, and many other advanced functions.

The advanced functionality of handheld mobile devices sometimes makes extended use of them desirable. Holding such devices for extended periods of time can be uncomfortable and inconvenient, and setting them down may not provide an optimal experience in using the device. Similarly, for handheld mobile devices that have picture and video recording capability, holding the devices during video capture can result in less-than-optimal picture and video quality due to the inherent movement of a person holding such devices.

### SUMMARY

Handheld electronic device holders are disclosed that may enable nearly any smartphone, tablet computer, or other handheld electronic device to be securely coupled to a holder for placing at a desired orientation on a support surface or tripod camera mount. The adapter may include first and second brackets slidably joined together with one another and moveable to expand away from, and contract toward, one another along an operating path. Each bracket may have a slider and a jaw that is generally orthogonal to the sliding portion. The jaw of each bracket may have a clamping face that makes an acute angle with the slider and is opposed to the clamping face of the other bracket. The clamping faces may be coated with a resilient, slip resistant material. A securement portion may be provided to allow the jaws to the set at a desired distance.

In some embodiments, an electronic device holder may include a body having a first jaw portion; an arm having a second jaw portion, wherein the arm is configured to slideably engage with the body such that the first jaw portion and the second jaw portion face each other and the distance between the first jaw portion and the second jaw portion is extendable; and a securement portion configured to selectively fix the distance between the first jaw portion and the second jaw portion. The securement portion may also include a threaded member configured to compress the arm against the body.

The first jaw portion and the second jaw portion may be configured to securably grip to the electronic device. The holder is configured to hold at least a portion of the electronic device away from a surface supporting the electronic device and holder. Each of the first jaw and second jaw may include friction pads formed from a resilient material.

The holder may also include a flashdrive. The electronic device may be a smartphone, a tablet computer, ebook reader, media player, or a handheld electronic game device. A decorative element may also be coupled to one of either the body or the arm. The securement portion may extend through a slot cut out of the body or the arm and into the other one of the body or the arm. The first jaw portion and the second jaw portion may be configured to selectively grip the electronic device using the securement portion.

Some methods of securing an electronic device for hands-free use may include placing the electronic device between adjustable jaws of a holder device; adjusting the adjustable jaws such that the adjustable jaws securely grip the electronic device; and locking the adjustable jaws in the secure grip of the electronic device. The locking may be performed by tightening a securement portion. The securement portion may include a thumbscrew.

The electronic device and the holder may be placed on a support surface such that at least a portion of the electronic device is supported away from the support surface by the holder. Additionally, the holder device may be secured to a tripod.

### BRIEF DESCRIPTION OF THE DRAWINGS

The following description can be better understood in light of the Figures, in which:

FIG. 1 is an isometric exploded view of an exemplary embodiment of a handheld electronic device holder;

FIG. 2 is an isometric assembled view of an exemplary embodiment of a handheld electronic device holder;

FIG. 3 is an isometric assembled view of an exemplary embodiment of a handheld electronic device holder;

FIG. 4 is an isometric assembled view of an exemplary embodiment of a handheld electronic device holder;

FIG. 5 is a top plan view of an exemplary embodiment of a handheld electronic device holder;

FIG. 6 is an isometric exploded view of an exemplary embodiment of a handheld electronic device holder;

FIG. 7 is an isometric assembled view of an exemplary embodiment of a handheld electronic device holder;

FIG. 8 is an isometric view of an exemplary embodiment of a handheld electronic device holder;

FIG. 9 is an isometric assembled view of an exemplary embodiment of a handheld electronic device holder;

FIG. 10 is an isometric assembled view of an exemplary embodiment of a handheld electronic device holder;

FIG. 11 is a top plan view of an exemplary embodiment of a handheld electronic device holder;

FIG. 12 is an isometric exploded view of an exemplary embodiment of a handheld electronic device holder;

FIG. 13 is an isometric exploded view of an exemplary embodiment of a handheld electronic device holder;

FIG. 14 is a plan view of the end of an exemplary embodiment of a handheld electronic device holder;

FIG. 15 is an isometric view of an exemplary embodiment of a handheld electronic device holder;

FIG. 16 is an alternative isometric view of an exemplary embodiment of a handheld electronic device holder;

FIG. 17 is an isometric view of an exemplary embodiment of a handheld electronic device holder;

FIG. 18 is an isometric view of an exemplary embodiment of a handheld electronic device holder;

FIG. 19 is an isometric view of an exemplary embodiment of a handheld electronic device holder;

FIG. 20 is a partially-disassembled isometric view of an exemplary embodiment of a handheld electronic device holder;

FIG. 21 is an exploded view of an exemplary embodiment of a handheld electronic device holder;

FIG. 22 is an exploded view of an exemplary embodiment of a handheld electronic device holder;

FIG. 23 is an isometric view of an exemplary embodiment of a handheld electronic device holder with a flashdrive; and

FIG. 24 is an isometric view of an exemplary embodiment of an exemplary embodiment of a handheld electronic device holder with a flashdrive.

The Figures illustrate specific aspects of the described systems and methods of mobile electronics holders. Together with the following description, the Figures demonstrate and explain the principles of the structures, methods, and principles described herein. In the drawings, the thickness and size of components may be exaggerated or otherwise modified for clarity. The same reference numerals in different drawings represent the same element, and thus their descriptions will not be repeated. Furthermore, well-known structures, materials, or operations are not shown or described in detail to avoid obscuring aspects of the described devices.

### DETAILED DESCRIPTION

The following description supplies specific details in order to provide a thorough understanding. Nevertheless, the skilled artisan will understand that the described stands and tripod adapters for handheld electronic devices and methods of making and using them can be implemented and used without employing these specific details. Indeed, the described stands for handheld electronic devices and methods of making and using them can be placed into practice by modifying the described stands and methods and can be used in conjunction with any other apparatus and techniques conventionally used in the industry. For example, while the description below focuses on stands for use with smartphones, the similar stands may be used with tablet computers, ebook readers, media players, handheld video game devices, GPS, etc.

In addition, as the terms on, disposed on, attached to, connected to, or coupled to, etc. are used herein, one object (e.g., a material, element, structure, member, etc.) can be on, disposed on, attached to, connected to, or coupled to another object—regardless of whether the one object is directly on, attached, connected, or coupled to the other object or whether there are one or more intervening objects between the one object and the other object. Also, directions (e.g., on top of, below, above, top, bottom, side, up, down, under, over, upper, lower, lateral, orbital, horizontal, etc.), if provided, are relative and provided solely by way of example and for ease of illustration and discussion and not by way of limitation. Where reference is made to a list of elements (e.g., elements a, b, c), such reference is intended to include any one of the listed elements by itself, any combination of less than all of the listed elements, and/or a combination of all of the listed elements. Furthermore, as used herein, the terms a, an, and one may each be interchangeable with the terms at least one and one or more.

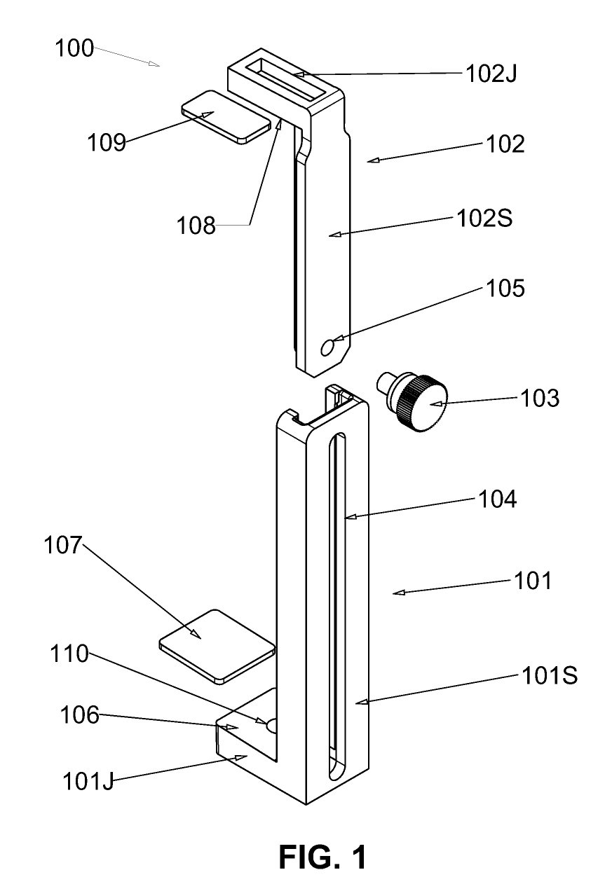

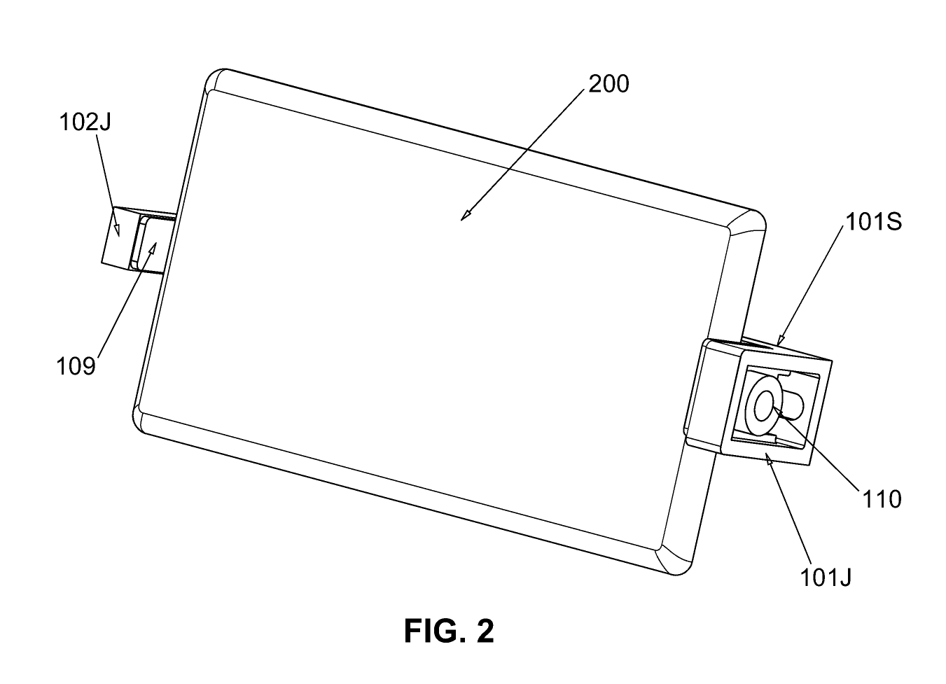

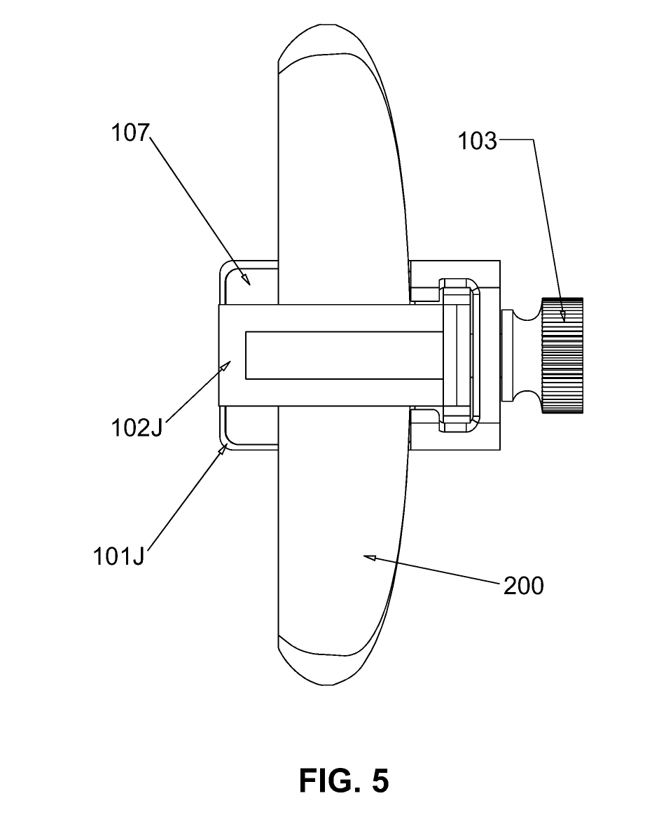

Handheld electronics holders and tripod adapters and methods of making and using the same are described in detail below with reference to the attached drawing figures. Referring now to FIGS. 1-5, holder 100 may include first bracket 101, second bracket 102, and thumbscrew 103. Second bracket 102 may be slidable within first bracket 101. Thumbscrew 103 may pass through a longitudinal slot 104 in first bracket 101 and engage threaded aperture 105 in second bracket 102.

First bracket 101 may include slider portion 101S and jaw portion 101J. Jaw portion 101J may be generally orthogonal to and unitary with slider portion 101S. Jaw portion 101J may include clamping face 106 to form an acute angle with slider portion 101S. Clamping face 106 may be covered with friction pad 107. Friction pad 107 may be formed of any suitable material to adequately grip electronic device 200. For example, friction pad 107 may be formed of any material that reduces potential damage to the finish or components of an electronic device being held, for example a resilient material, such as silicone rubber, natural rubber, neoprene rubber, synthetic isoprene rubber, or other similar resilient compound. Resilient materials may also aid in providing a secure grip of electronic device 200 with less force. In some embodiments, holder 100 may be coated with a slip-resistant and/or resilient material such that friction pads 107, 109 may be a portion of a continuous coating of holder 100.

Likewise, second bracket 102 may include slider portion 102S and jaw portion 102J. Jaw portion 102J may be generally orthogonal to and unitary with slider portion 102S. Jaw portion 102J may also include clamping face 108 forming an acute angle with slider portion 102S. Similar to clamping face 106, clamping face 108 may be covered with friction pad 109 formed of material suitable to hold electronic device 200.

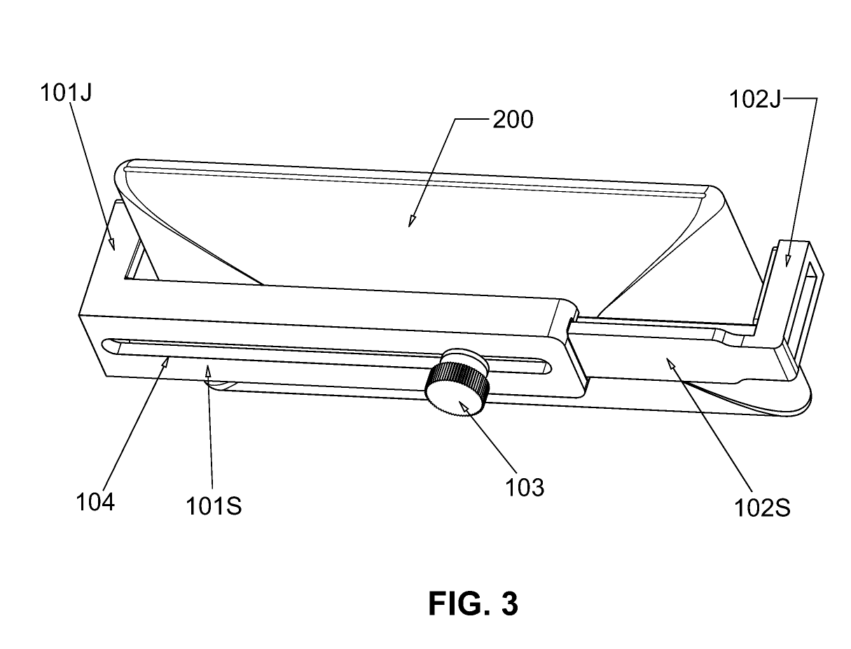

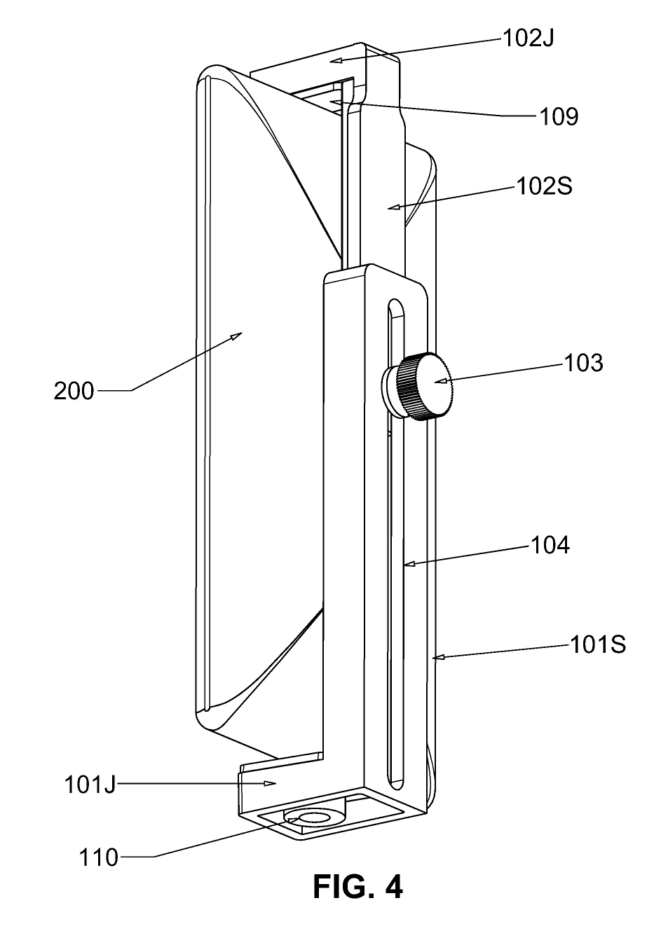

Slider portions 101S, 102S may operate cooperatively to allow adjustment in the distance between clamping faces 106, 108. For example, as shown in FIGS. 3 and 4, slider portion 102S may engage in the slot of slider portion 101S such that second bracket 102 and first bracket 101 can telescopically slide with respect to each other. First bracket 101 and second bracket 102 may thereby be slidably joined together and moveable to expand away from and contract toward one another along a linear operating path.

Thumbscrew 103 may be provided to secure first bracket 101 and second bracket 102 at a fixed distance between clamping faces 106, 108. Opposing clamping faces 106, 108 and their respective slider portions 101S, 102S may provide a placement for a smartphone or other handheld electronic device 200 to be securely held between jaws 101J and 102J. Second bracket 102 may be equipped with threaded aperture 105 to threadably engage thumbscrew 103. Thumbscrew 103 may be any suitable fastener, such as a typical thumbscrew used with other devices, such as those typically used to secure a camera to a tripod. In some embodiments, other securement devices and methods may be used to selectively set the distance between opposing clamping faces 106, 108. For example, a camming lock, button lock, detents, or other similar fasteners and methods may be used to easily adjust and securely hold holder 100 at a desired configuration.

Jaw 101J may also include threaded aperture 110, which is compatible with standard threaded attachments on tripods and other similar stands with screw-in fasteners, similar to standard attachments for standard still and video cameras.

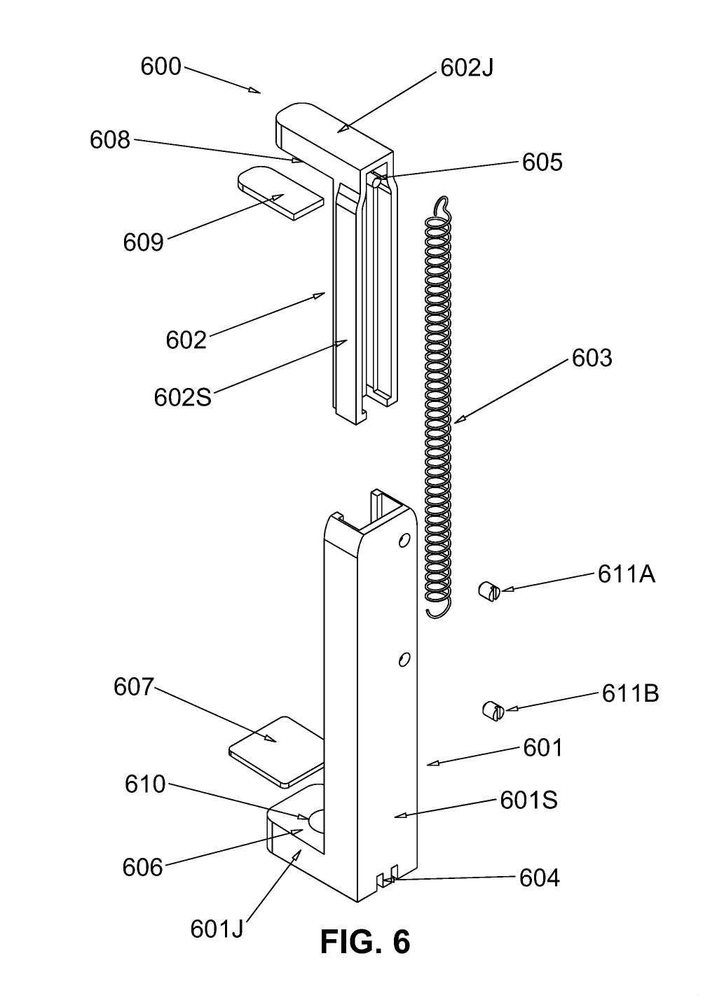

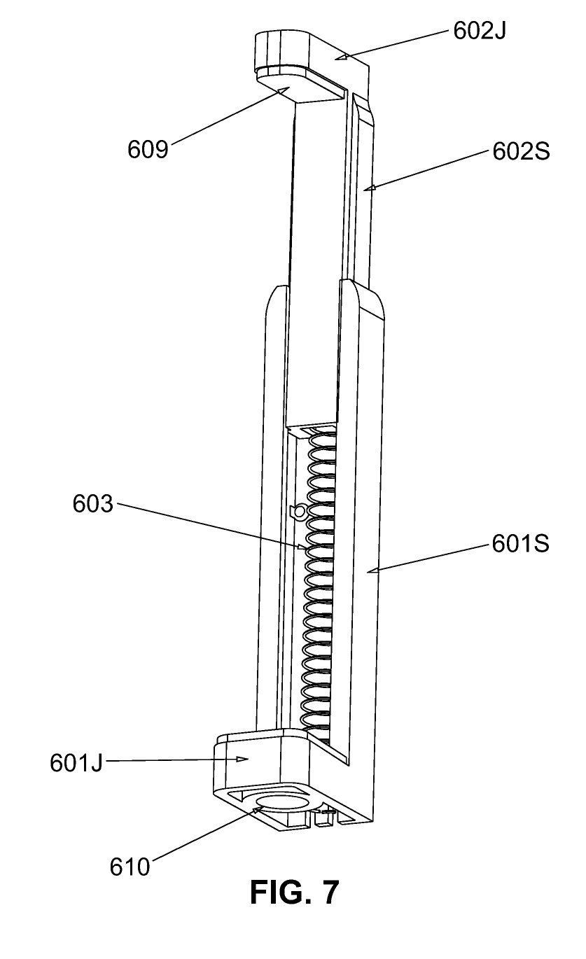

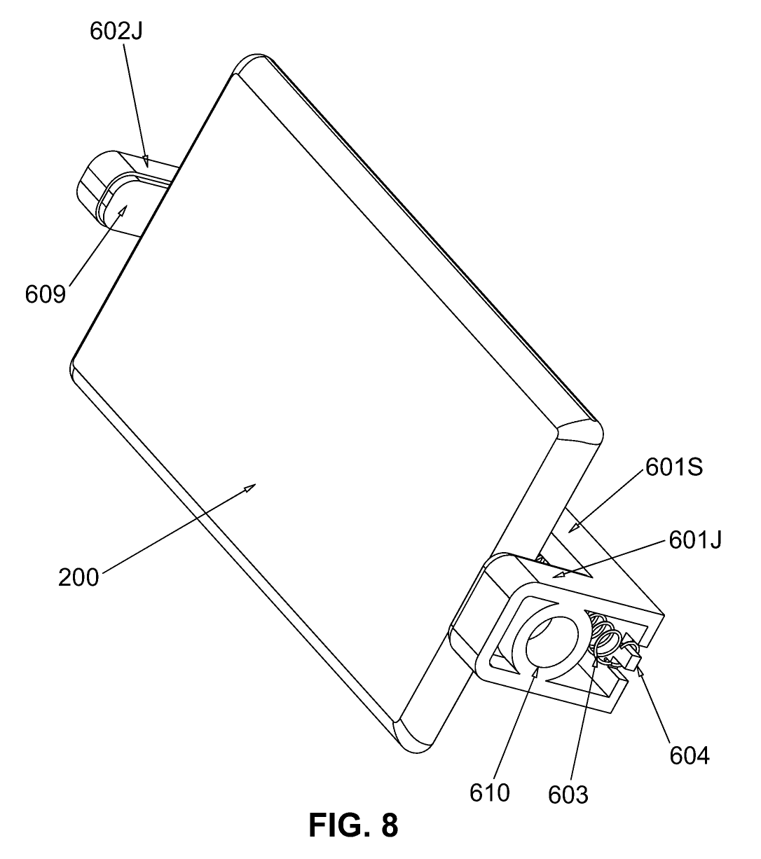

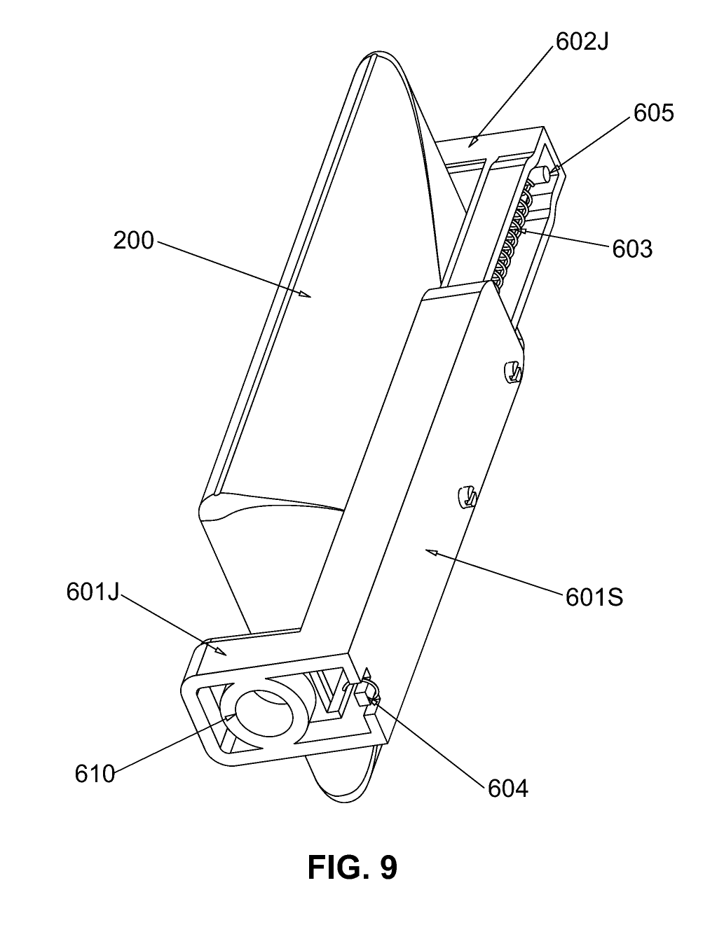

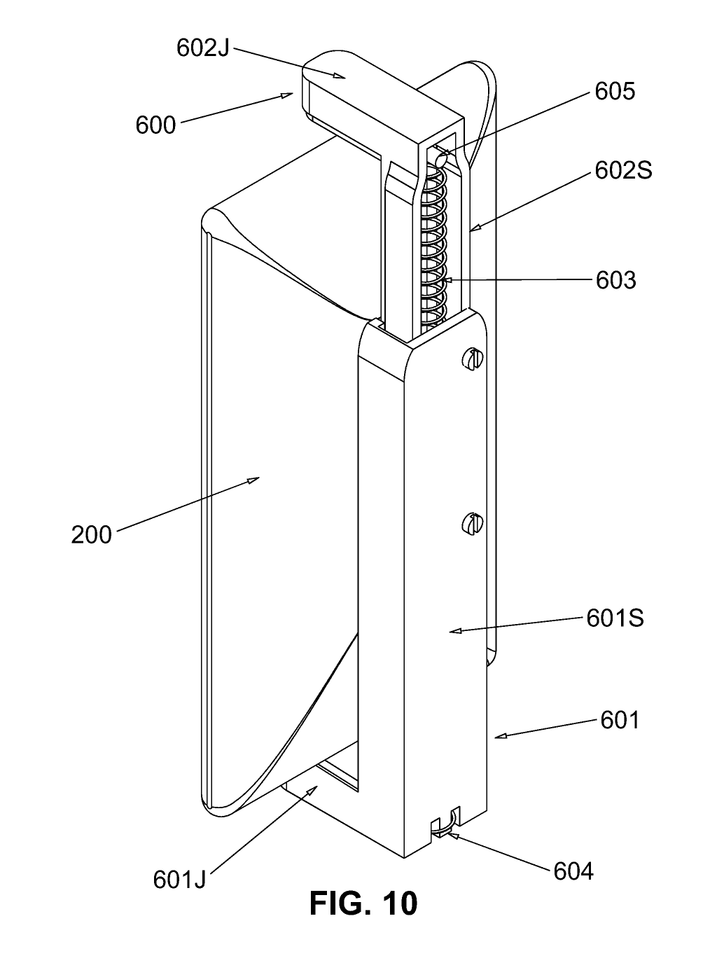

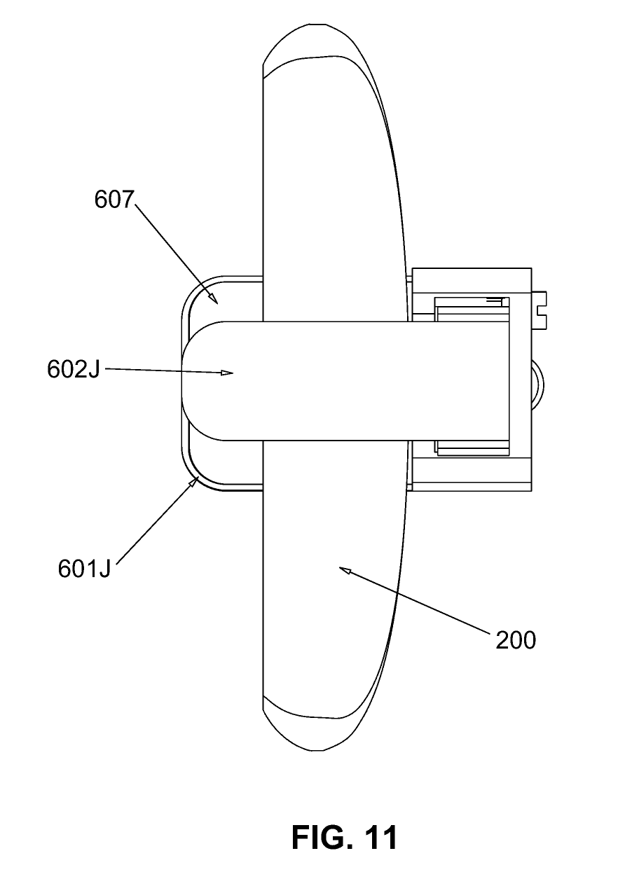

Turning now to FIGS. 6-11, holder 600, similar to holder 100, may include first bracket 601, second bracket 602 slidable within the first bracket 601, and biasing element 603. Biasing element 603 may be suspended between first projection 604 on first bracket 601 and second projection 605 on second bracket 602. Biasing element 603 may be formed of any suitable material, such as a coil spring as shown, an elastic cord or band, leaf spring, cantilevered member, or any other biasing material.

In some embodiments, biasing element 603 may positioned with respect to first bracket 601 and second bracket 602 such that when first bracket 601 and second bracket 602 are extended away from each other, biasing element 603 is stretched, biasing friction pad 607 towards friction pad 609. Similarly, in other embodiments, biasing element may be positioned such that when first bracket 601 and second bracket 602 are extended away from each other, biasing element 603 is compressed, biasing friction pad 607 towards friction pad 609.

Similar to holder 100 described above, first bracket 601 may include slider portion 601S and jaw portion 601J, with jaw portion 601J being generally orthogonal to and unitary with the slider portion 601S. Jaw portion 601J may have clamping face 606 formed at an acute angle with slider portion 101S Likewise, second bracket 602 may include slider portion 602S and jaw portion 602J, with jaw portion 602J being generally orthogonal to and unitary with slider portion 602S. Jaw portion 602J may also include clamping face 608 formed at an acute angle with slider portion 602S.

Clamping faces 606 and 608 may be covered with friction pads 607 and 609 similar to friction pads 107 and 109. The acute angle made by each of the clamping faces 606, 608 and their respective slider portions 601S, 602S may allow a smartphone or other handheld electronic device 200 to be securely held between jaws 601J and 602J by the biasing force of biasing member 603.

First bracket 601 and second bracket 602 may be slidably joined together and moveable to expand away from, and contract toward, one another along a linear operating path. Screw-in pins 611A and 611B may provide locking or fixing capabilities to lock or fix the relative position of first bracket 601 and second bracket 601. Pins 611A and 611B may be any suitable locking device such as thumbscrews, camming pins, etc. Additionally, the pins may be used as alternative locations for anchoring biasing member 603 on first bracket 601, to make holder 600 adjustable to be used with electronic devices of various sizes and shapes.

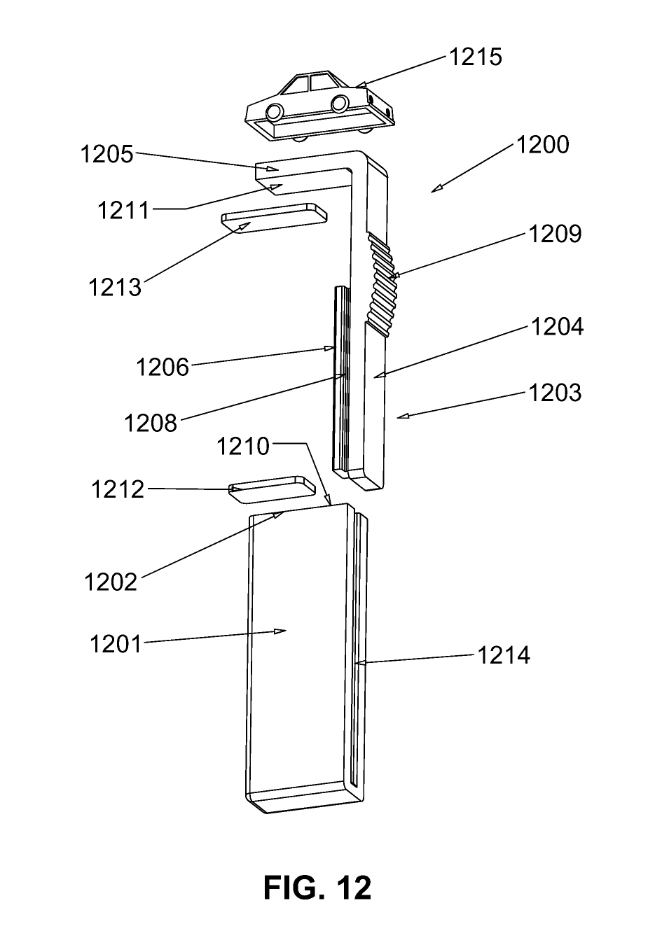

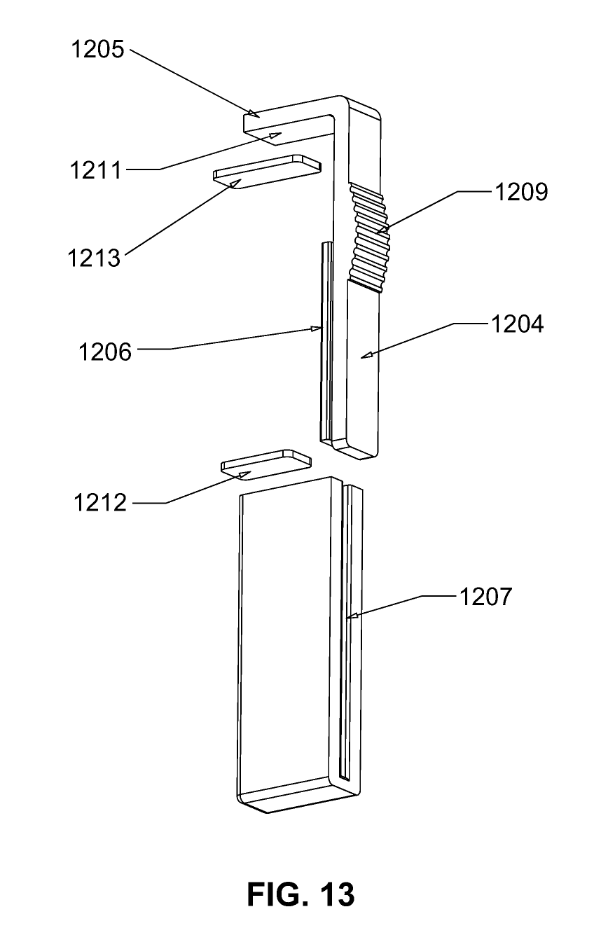

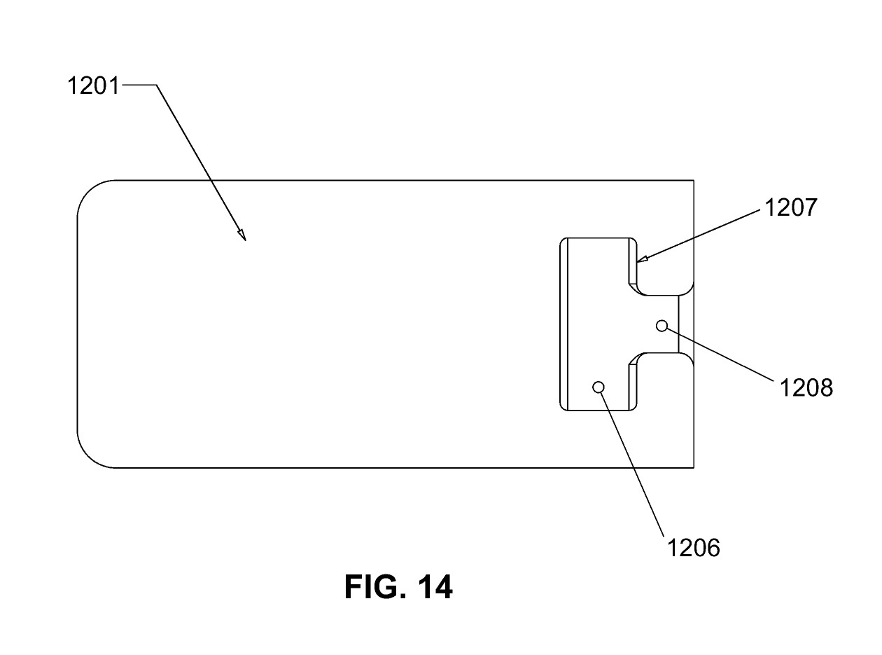

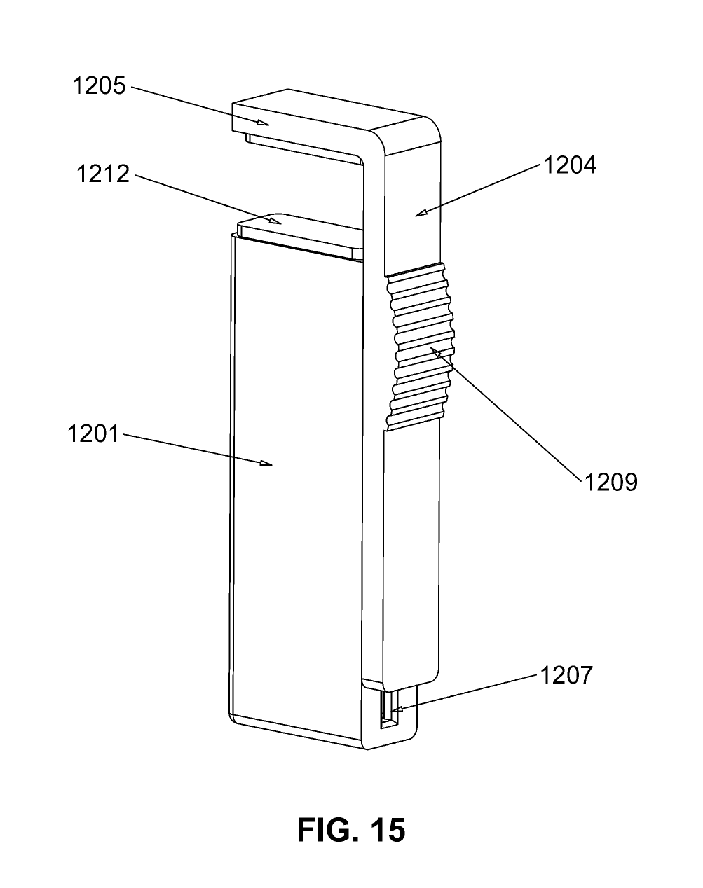

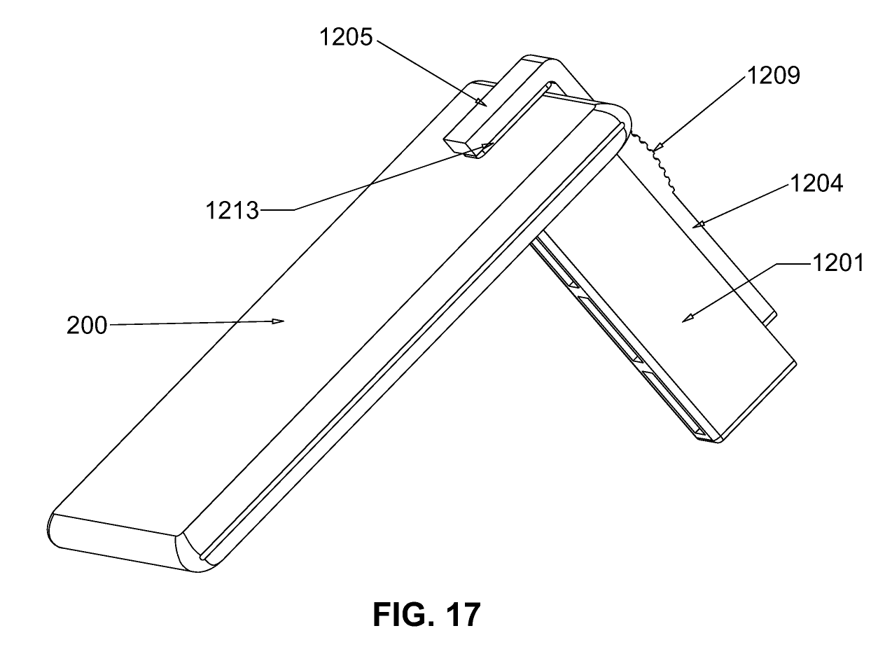

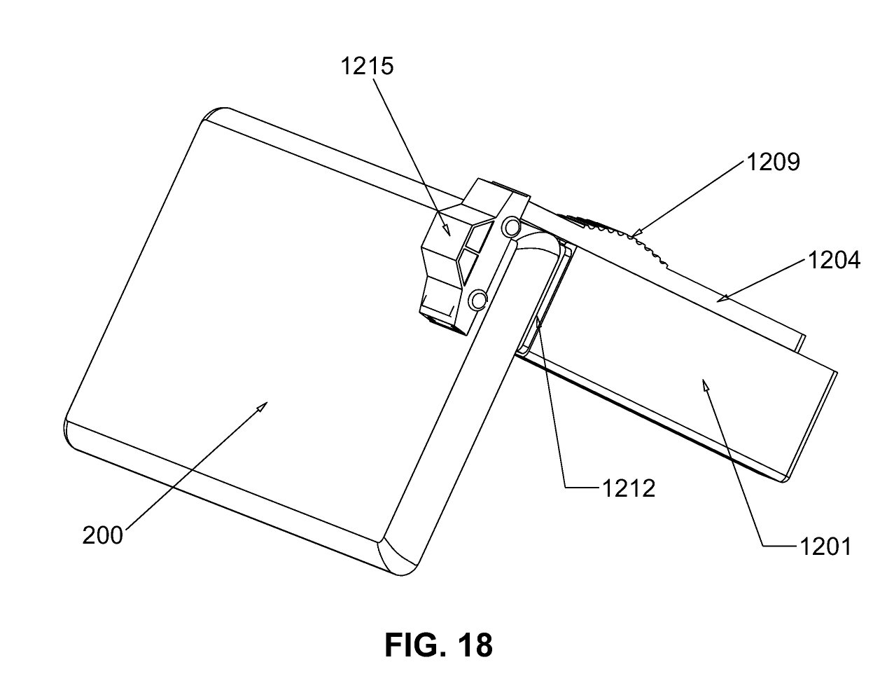

Referring now to FIGS. 12-18, holder 1200 may include main body 1201 and sliding bracket 1203. Main body 1201 may include first jaw 1202, and sliding bracket 1203 may include longitudinal arm portion 1204 and second jaw 1205. Second Jaw 1205 may be generally orthogonal to arm portion 1204. Arm portion 1204 may have a longitudinal shackle 1206 that is unitary with the arm portion 1204 and slides within a channel 1207 within the main body 1201. In other embodiments, the channel may be located on the slider and the shackle on the main body. Similarly, in some embodiments, the arm portion may telescope within the body or vice-versa.

Elongated neck 1208 may join arm portion 1204 and shackle 1206. Main body 1201 and sliding bracket 1203 may be slidably joined together with one another and moveable to expand away from, and contract toward, one another along a linear operating path. In some embodiments, as shackle 1206 enters the channel 1207, sliding bracket 1203 may become trapped therein so that it can move only linearly with respect to main body 1201. Slider portion 1204 may be equipped with a serrated thumb rest 1209, which may permit slider portion 1204 to be extended from and retracted into main body 1201.

First jaw 1202 and second jaw 1205 may have clamping faces 1210 and 1211, respectively, which, similar to embodiments discussed above, may be covered with first and second resilient pads 1212 and 1213, respectively. Linear slot 1214, which may be continuous with the channel 1207, may be sufficiently narrow so as to achieve a friction fit with neck 1208. The friction may be sufficient that first jaw 1202 and second jaw 1205 may be set to a desired spacing that securely holds the electronic device 200. In some embodiments, linear slot 1214 and/or channel 1207 may include detents to assist in holding the distance between first jaw 1202 and second jaw 1205.

In some embodiments, decorative additions may be provided for aesthetic value, such as decorative figure in the form of an automobile 1215, as shown. Such decorative additions may provide additional structure and may be used to identify a particular stand or to brand the stands. Decorative additions 1215 may attach to jaw 1205 of stand 1200 or to jaw portion 102J. Similarly, decorative additions 1215 may be attached or removably attached to any portion of stand 1200.

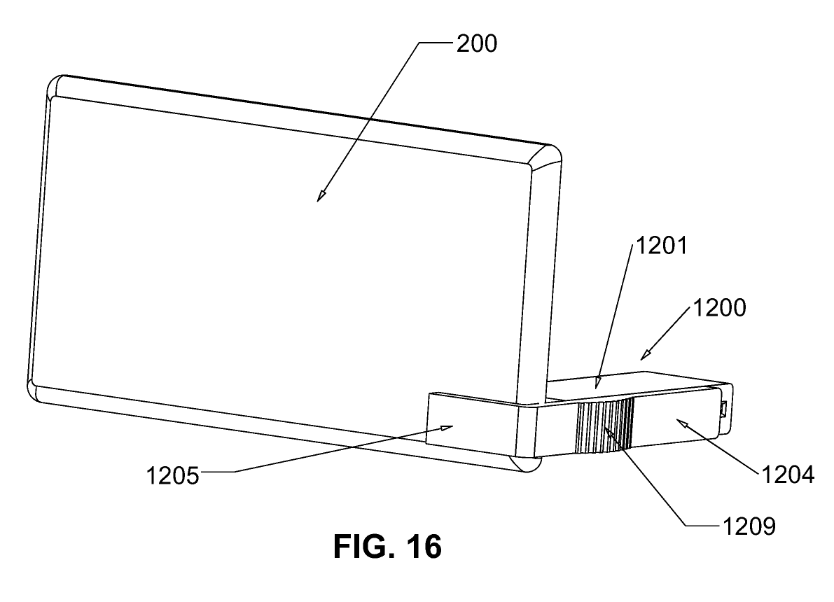

As shown in FIGS. 16-18, stand 1200 may be secured to an edge or corner of smartphone 200 so that the assembly may rest on a portion of stand 1200 and an edge or other portions of smartphone 200. By securing stand 1200 (or any other embodiment of stand disclosed herein or consistent with the disclosed embodiments) to an edge of a smartphone 200 (or any other handheld electronic device), smartphone 200 may be positioned to be viewed at a desired angle and/or orientation when being used.

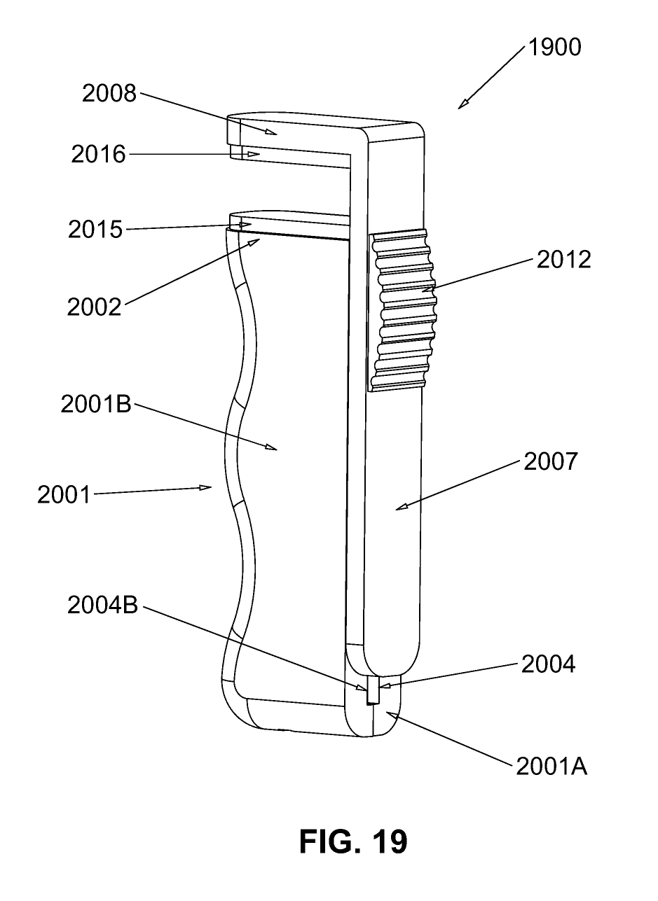

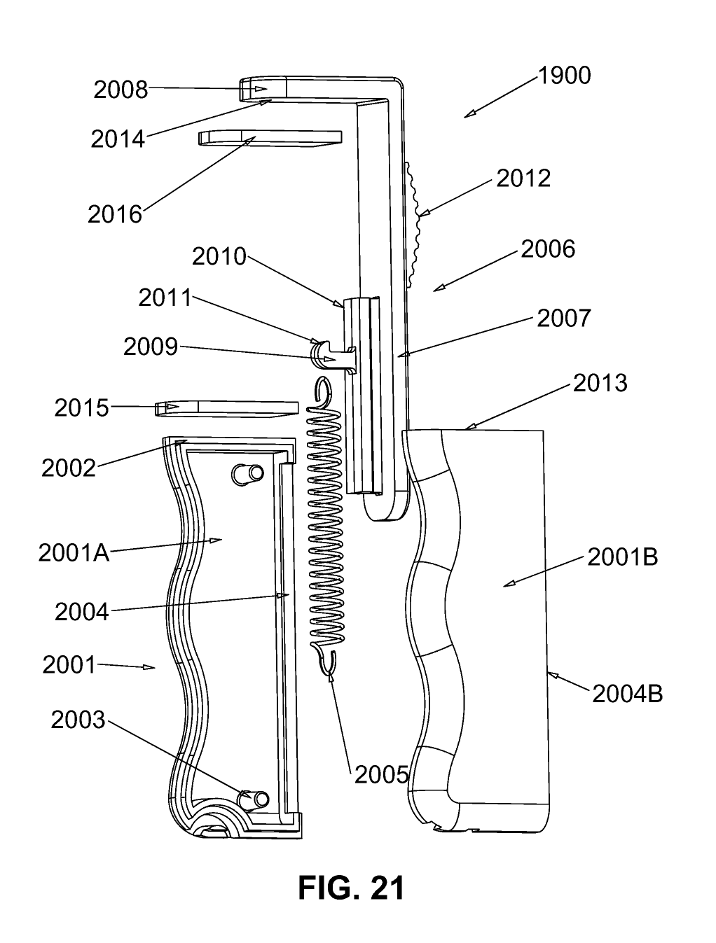

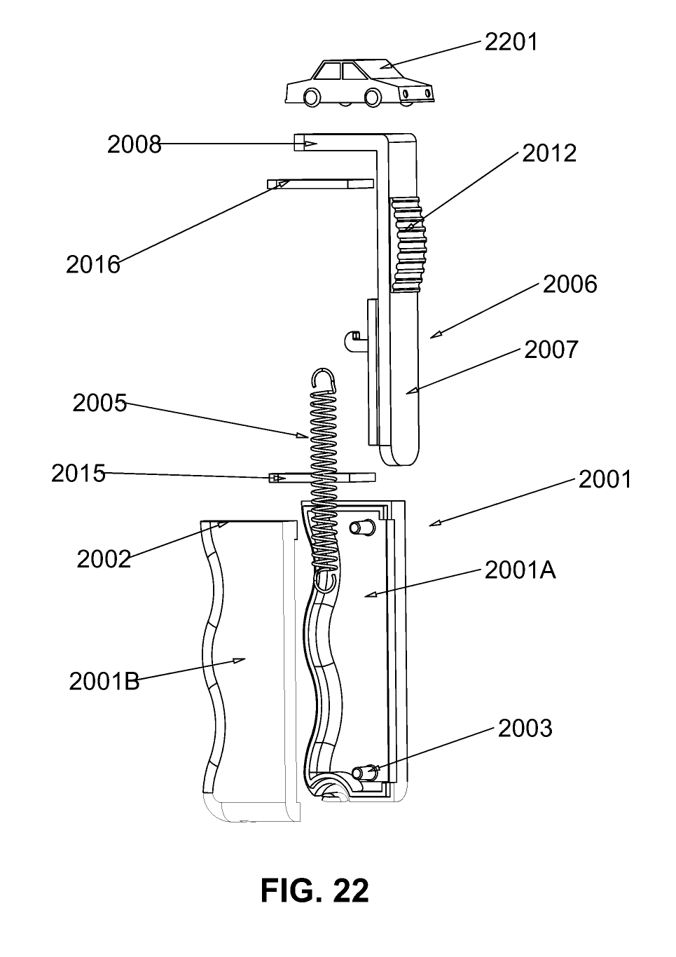

In some embodiments, such as those shown in FIGS. 19-22, the adjustable-jaw caliper stand 1900 may include main body assembly 2001, with cover 2001B securable to body portion 2001A. Main body 2001 may include first jaw 2002, biasing member securing pin 2003, and a portion of retention channel 2004. Cover 2001B may provide another portion 2004B of retention channel 2004. Stand 1900 may also include biasing member 2005, and sliding bracket 2006 having longitudinal arm portion 2007.

Arm portion 2007 may include second jaw 2008 positioned generally orthogonal to arm portion 2007. Arm portion 2007 may have longitudinal shackle 2010 unitary with arm portion 2007 that slides within channel 2004 when formed by joining main body 2001A and cover 2001B. Elongated neck 2010 may join arm portion 2007 and shackle 2010. Biasing member retention hook 2011 may protrude from longitudinal shackle 2010 on shaft 2009.

Sliding bracket 2006 may be installed within the main body 2001A and biasing member 2005 may be stretched and suspended (or compressed) between securing pin 2003 and retention hook 2011. Cover 2001B may be secured to the main body 2001A, thereby slidably trapping sliding bracket 2006 within main body assembly 2001. The distance between first jaw 2002 and second jaw 2008 may be adjustable by moving sliding bracket 2006 in or out of main body assembly 2001. Arm portion 2007 may be equipped with a serrated thumb rest 2012, which may be used with the arm portion 2007 to extend from and retract into main body assembly 2001.

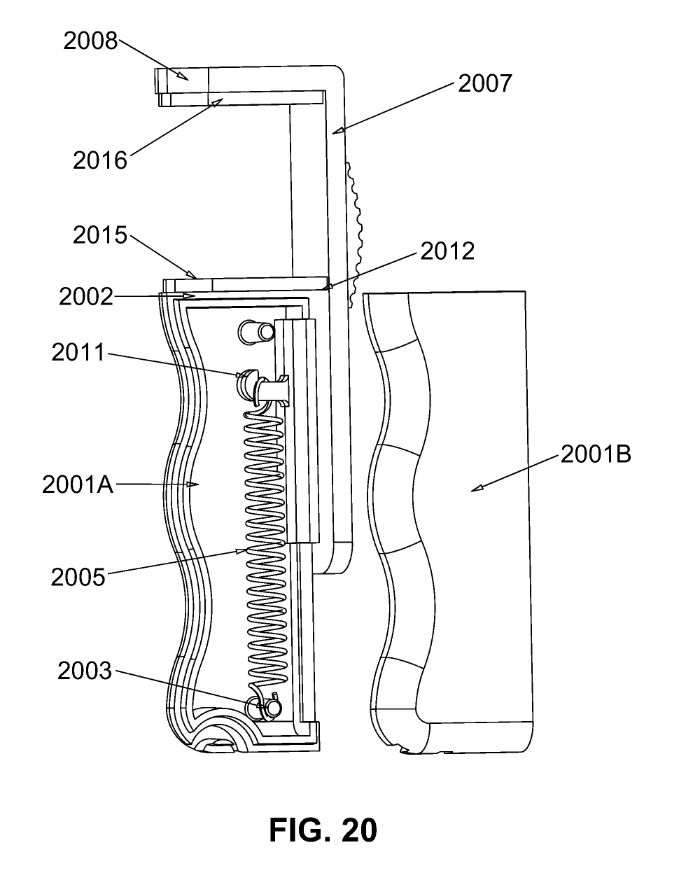

Serrated thumb rest 2012 may provide friction and grip to facilitate moving arm portion with respect to main body 2001. Main body assembly 2001 may also include surface features on the opposite side of the main body from retention channel 2004. The surface features shown in FIGS. 20-24 are wavy contours to ergonomically accommodate fingers. Surface features may provide additional grip when moving arm portion 2007 using thumb rest 2012 to securely and easily adjust the opening between first jaw 2002 and second jaw 2008.

First jaw 2002 and second jaw 2008 may include clamping faces 2013 and 2014, respectively, which may be optionally covered with first and second resilient pads 2015 and 2016, respectively. In contrast to the tight clearances employed to maintain first jaw 1202 and second jaw 1205 of stand 1200 a fixed distance apart, first second jaws 2002 and 2008, respectively of stand 2000 may be pulled toward one another by biasing member 2005. As discussed above, any biasing member discussed herein may be any biasing member arranged in a compressive or extended configuration to provide clamping force to the various stand embodiments.

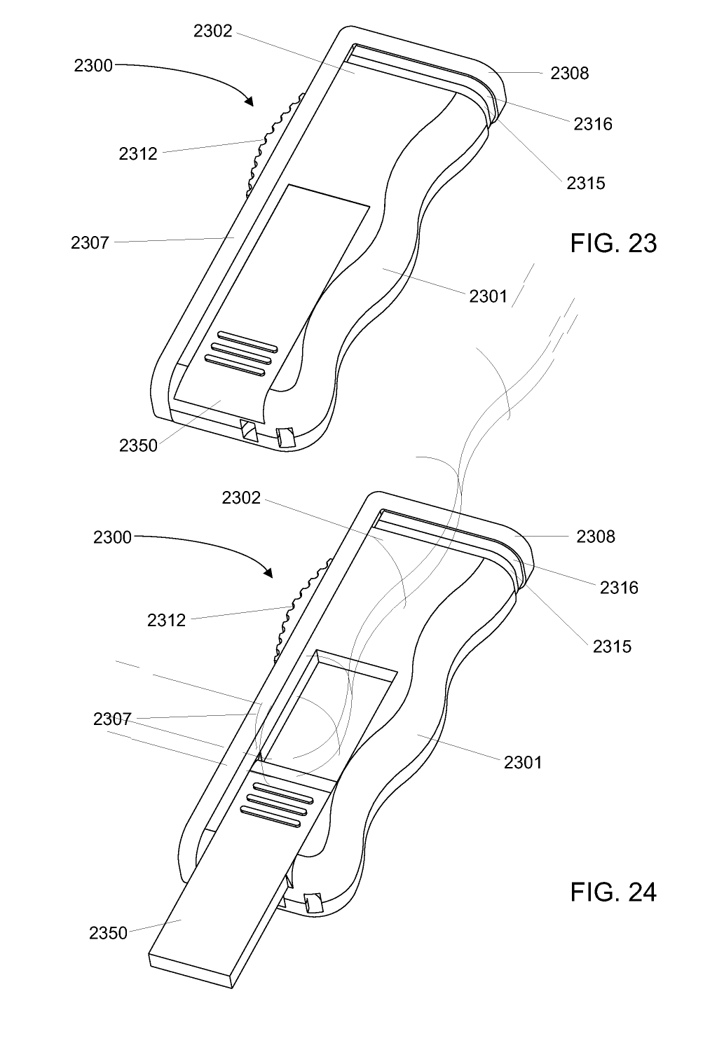

In some embodiments, such as those shown in FIGS. 23-24, adjustable-jaw caliper stand 2300 may include main body assembly 2301, arm portion 2307, and flashdrive 2350. Main body 2301 may include first jaw 2302. Stand 2300 may also includes longitudinal arm portion 2307. Arm portion 2307 may include second jaw 2308 positioned generally orthogonal to arm portion 2007. First jaw 2302 and second jaw 2308 may include clamping faces which may be optionally covered with first and second resilient pads 2315 and 2316, similar to other embodiments discussed above.

Flashdrive 2350 may be insertable into main body 2301 or otherwise attachable to main body 2301. Flashdrive 2350 may be included to provide convenient and easy storage and portability of a flash drive that can be used with various electronic devices having an USB interface. As shown in FIG. 24, flashdrive 2350 may be extendable, reversible, or removable from main body 2301. In other embodiments, flashdrive 2350 may be formed with or attached to any portion of embodiments of stands as discussed herein.

The various components of embodiments of stands discussed above may be used with other embodiments as desired for functionality. Similarly, the various components may be formed of any suitable material, such as metals, plastics, wood, foam, etc., depending on the desired appearance and function. Similarly, the size of the various handheld electronic device stands disclosed above may be appropriate for use with a desired device, or a single size may be appropriate for any handheld electronic devices.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, the examples and embodiments, in all respects, are meant to be illustrative only and should not be construed to be limiting in any manner.

1. An electronic device holder, comprising:
a body having a first jaw portion;
an arm having a second jaw portion, wherein the arm is configured to slideably engage with the body such that the first jaw portion and the second jaw portion face each other and the distance between the first jaw portion and the second jaw portion is extendable; and
a securement portion configured to selectively fix the distance between the first jaw portion and the second jaw portion.

2. The holder of claim 1, wherein the securement portion comprises a threaded member configured to compress the arm against the body.

3. The holder of claim 1, wherein the first jaw portion and the second jaw portion are configured to securably grip to the electronic device.

4. The holder of claim 3, wherein the holder is configured to hold at least a portion of the electronic device away from a surface supporting the electronic device and holder.

5. The holder of claim 1, further comprising a flashdrive.

6. The holder of claim 1, each of the first jaw and second jaw include friction pads.

7. The holder of claim 6, wherein friction pads are formed from a resilient material.

8. The holder of claim 1, further comprising a decorative element coupled to one of the body or the arm.

9. The holder of claim 1, wherein the securement portion extends through a slot cut out of the body or the arm and into the other one of the body or the arm.

10. The holder of claim 1, wherein the first jaw portion and the second jaw portion are configured to selectively grip the electronic device using the securement portion.

11. The holder of claim 1, wherein the electronic device is a smartphone.

12. The holder of claim 1, wherein the electronic device is a tablet computer, ebook reader, media player, or a handheld electronic game device.

13. A method of securing an electronic device for hands-free use, comprising:
placing the electronic device between adjustable jaws of a holder device;
adjusting the adjustable jaws such that the adjustable jaws securely grip the electronic device; and
locking the adjustable jaws in the secure grip of the electronic device.

14. The method of claim 13, wherein the electronic device is a smartphone.

15. The method of claim 13, wherein the locking is performed by tightening a securement portion.

16. The method of claim 15, wherein the securement portion comprises a thumbscrew.

17. The method of claim 13, further comprising placing the electronic device and the holder on a support surface such that at least a portion of the electronic device is supported away from the support surface by the holder.

18. The method of claim 13, wherein the holder device comprises a body portion and an arm portion.

19. The method of claim 18, wherein the arm portion and the body portion are slidably adjustable with respect to each other.

20. The method of claim 13, further comprising securing the holder device to a tripod.
